(19) United States
(12) Patent Application Publication
(10) Pub. No.: US 2026/0082629 A1
(43) Pub. Date: Mar. 19, 2026

(54) HIGH-TEMPERATURE SILICIDE CONTACT FOR BACKSIDE SOURCE/DRAIN CONTACTS

(71) Applicant: QUALCOMM Incorporated, San Diego, CA (US)

(72) Inventors: Abhishek JAIN, San Diego, CA (US); Junjing BAO, San Diego, CA (US); John Jianhong ZHU, San Diego, CA (US); Giridhar NALLAPATI, San Diego, CA (US)

(21) Appl. No.: 18/885,189

(22) Filed: Sep. 13, 2024

(51) Int. Cl. H01L 29/417; H01L 21/28; H01L 29/06; H01L 29/49; H01L 29/66; H01L 29/775; H01L 29/786

(52) U.S. Cl. CPC H10D 30/6729; H10D 64/0131; H10D 64/668; H10D 30/014; H10D 30/43; H10D 30/6757; H10D 62/121

(57) ABSTRACT

A semiconductor structure having a high-temperature silicide contact for backside source/drain (S/D) contacts and method for making the same is disclosed. In an aspect, the semiconductor structure comprises a substrate; a source/drain (S/D) structure comprising a lower S/D portion disposed above the substrate and an upper S/D portion disposed above the lower S/D portion, the lower S/D portion comprising a high temperature silicide structure and an etch stop material structure surrounding at least a portion of the high temperature silicide structure, the upper S/D portion comprising an epitaxial (EPI) material in contact with the high temperature silicide structure; and a backside metal structure that extends through the substrate and is in contact with the high temperature silicide structure.

### BACKGROUND OF THE DISCLOSURE

### 1. Field of the Disclosure

This disclosure relates generally to semiconductor wafer process, and more specifically to high-temperature silicide contact for backside source/drain (S/D) contacts, which may be used for backside power distribution network (BSPDN) direct contacts, and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes a substrate; a source/drain (S/D) structure comprising a lower S/D portion disposed above the substrate and an upper S/D portion disposed above the lower S/D portion, the lower S/D portion comprising a high temperature silicide structure and an etch stop material structure surrounding at least a portion of the high temperature silicide structure, the upper S/D portion comprising an epitaxial (EPI) material in contact with the high temperature silicide structure; and a backside metal structure that extends through the substrate and is in contact with the high temperature silicide structure.

In an aspect, a method for fabricating a semiconductor structure includes providing a substrate; forming, above the substrate, a lower portion of an S/D structure, comprising a high temperature silicide structure and an etch stop material structure that surrounds at least a portion of the high temperature silicide structure; forming, above the lower portion of the S/D structure, an upper portion of the S/D structure, comprising an EPI material that is in contact with the high temperature silicide structure; and forming a backside metal structure that extends through the substrate and is in contact with the high temperature silicide structure.

In an aspect, an apparatus includes a field effect transistor (FET) structure, wherein the FET structure comprises: a substrate; a gate structure, disposed above the substrate and comprising a vertical metal gate structure and a channel structure, the channel structure comprising a plurality of vertically-stacked channels extending horizontally through the vertical metal gate structure; an S/D structure, comprising a lower S/D portion, disposed above the substrate, comprising a high temperature silicide structure and an etch stop material structure surrounding at least a portion of the high temperature silicide structure, and further comprising an upper S/D portion, disposed above the lower S/D portion, comprising an EPI material in contact with a first end of each vertically-stacked channel of the plurality of vertically-stacked channels; and a backside metal structure that extends through the substrate and is in contact with the high temperature silicide structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIGS. 1A and 1B are top views of a portion of a semiconductor structure of an IC device having a high-temperature silicide contact for backside source/drain (S/D) contacts, according to aspects of the disclosure.

FIGS. 1C and 1D are cross-sectional views of a semiconductor structure of an IC device having a high-temperature silicide contact for backside source/drain (S/D) contacts, according to aspects of the disclosure.

FIG. 2 is a process flow diagram illustrating steps in a process for fabricating a semiconductor structure having a high-temperature silicide contact for backside S/D contacts, according to aspects of the disclosure.

FIGS. 3A-3K are cross-sections that illustrate steps in a process for fabricating a semiconductor structure having a high-temperature silicide contact for backside S/D contacts, according to aspects of the invention.

FIGS. 4A-4J are cross-sections that illustrate steps in a process for fabricating a semiconductor structure having a high-temperature silicide contact for backside S/D contacts, according to other aspects of the invention.

FIG. 5 is a flowchart of an example process associated with fabricating a semiconductor structure having a high-temperature silicide contact for backside S/D contacts, according to aspects of the disclosure.

FIG. 6 illustrates a mobile device in accordance with some examples of the disclosure.

FIG. 7 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A semiconductor structure having a high-temperature silicide contact for backside source/drain (S/D) contacts and method for making the same is disclosed. In an aspect, the semiconductor structure comprises a substrate; a source/drain (S/D) structure comprising a lower S/D portion disposed above the substrate and an upper S/D portion disposed above the lower S/D portion, the lower S/D portion comprising a high temperature silicide structure and an etch stop material structure surrounding at least a portion of the high temperature silicide structure, the upper S/D portion comprising an epitaxial (EPI) material in contact with the high temperature silicide structure; and a backside metal structure that extends through the substrate and is in contact with the high temperature silicide structure.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an integrated circuit device and a manufacturing method of making the integrated circuit device. Some aspects more specifically relate to semiconductor structures having a high-temperature silicide contact for backside S/D contacts. These contacts are applicable to gate-all-around structures and compatible with backside power distribution networks.

Particular aspects of the subject matter described in this disclosure can be implemented to realize one or more of the following potential advantages. The use of a frontside high-temperature silicide, rather than a low-temperature backside silicide, provides lower contact resistance, which improves circuit performance. Additionally, an extra backside etch step can increase the area of the contact surface between the backside metal and the high-temperature silicide, further reducing the contact resistance. The reduced contact resistance of these structures can benefit BSPDNs.

The words “exemplary” and/or “example” are used herein to mean “serving as an example, instance, or illustration. ” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

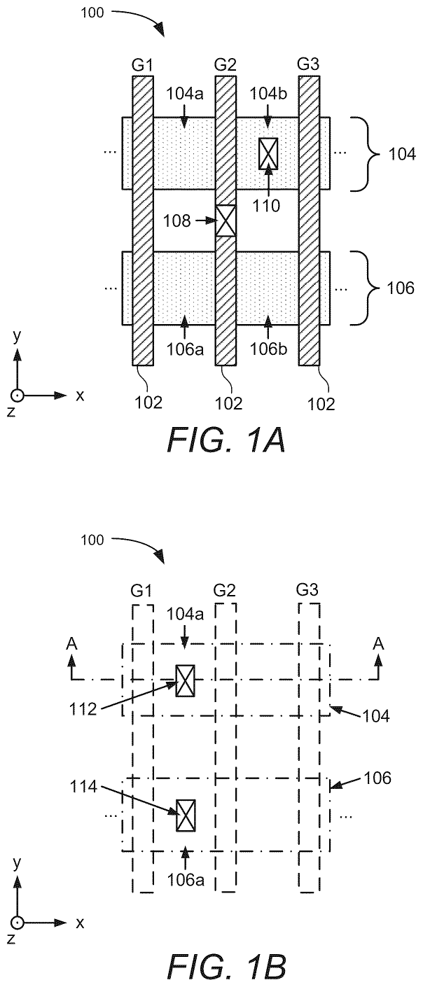

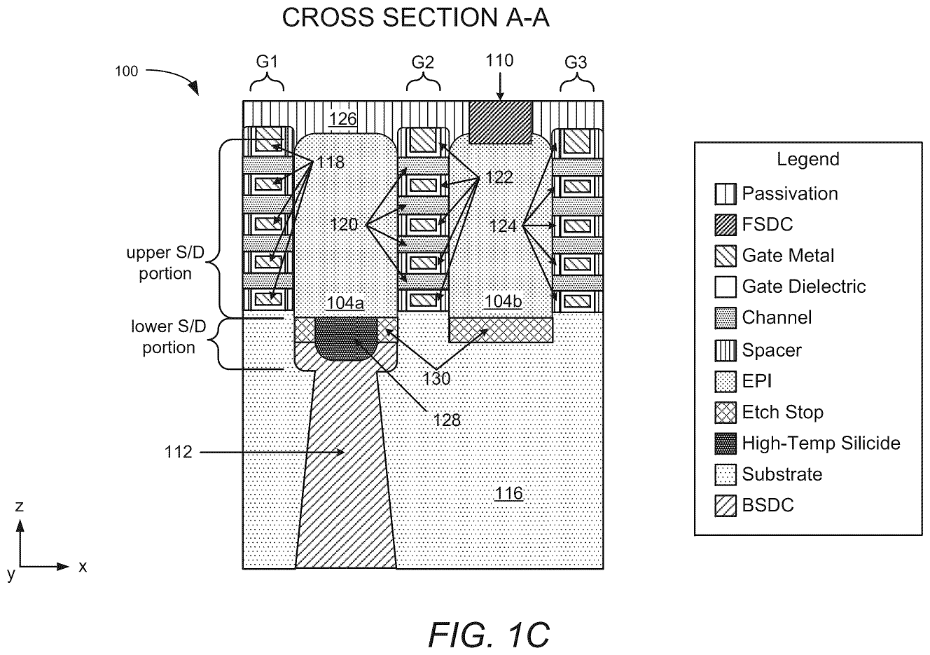

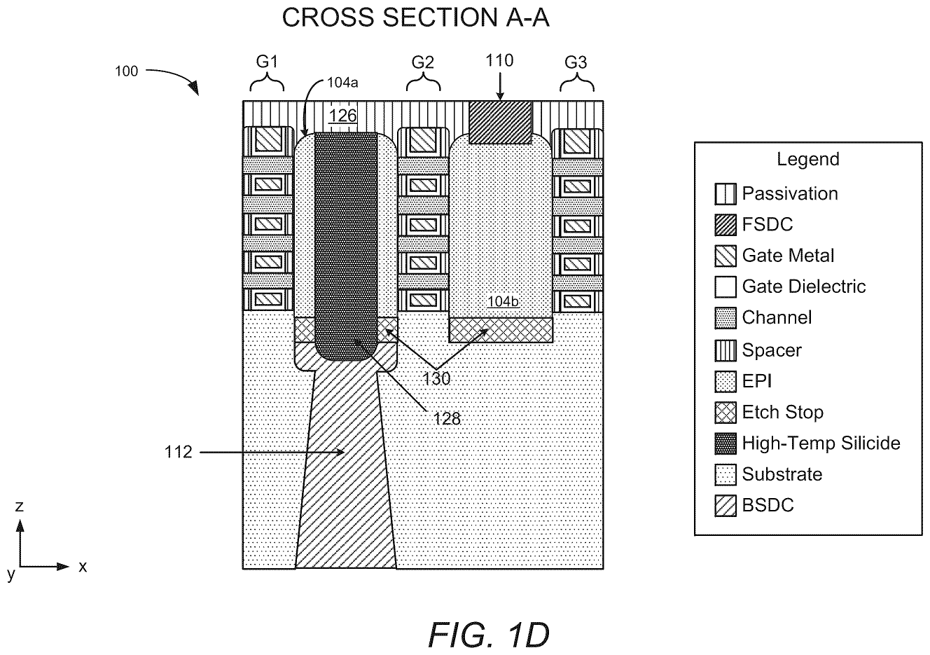

FIG. 1A and FIG. 1B are top views of a portion of a semiconductor structure 100 of an IC device having a high-temperature silicide contact for backside source/drain (S/D) contacts, with emphasis of elements at different vertical regions thereof, according to aspects of the disclosure. In particular, the elements shown in FIG. 1A shows the elements that may be above the elements shown in FIG. 1B in a vertical direction (e.g., the z direction corresponding to a direction leaving the plane of the drawing sheet). In some aspects, FIGS. 1A and 1B merely show some elements of the semiconductor structure 100 for illustration purposes, and other elements above and/or below the elements shown in FIGS. 1A and 1B may exist but not be shown in FIGS. 1A and 1B.

As shown in FIG. 1A and FIG. 1B, there are multiple gate structures 102, a first set of S/D structures 104 and a second set of S/D structures 106. In some aspects, the S/D structures comprise an epitaxial (EPI) material. For ease of description, the gate structures 102 are labeled G1, G2, and G3. The first set of S/D structures 104 is further divided into S/D 104a and S/D 104b. The second set of S/D structures 106 is further divided into S/D 106a and S/D 106b. Although three gate structures are shown, it will be appreciated that there may be a non-specific number of gate structures in a cell or a FET structure. FIG. 1A shows the location of a frontside gate contact (FSGC) 108 connected to gate G2 and the location of a frontside S/D contact (FSDC) 110 connected to S/D 104b. FIG. 1B shows the location of a backside S/D contact (BSDC) 112 connected to the S/D 104a through the substrate and the location of another BSDC 114 connected to the S/D 106a through the substrate.

FIG. 1C is a cross-sectional view of the semiconductor structure 100 along cut line A-A, according to aspects of the disclosure. Each gate structure G1-G3 is disposed above a substrate 116 and comprises a vertical metal gate structure 118 and a channel structure, the channel structure comprising a plurality of vertically-stacked channels 120 extending horizontally through the vertical metal gate structure 118. S/D 104a is located between G1 and G2, and S/D 104b is located between G2 and G3. A gate dielectric material 122 is disposed between the channels 120 and the vertical metal gate structure 118. A spacer material 124 is disposed between each gate structure and S/D structure. The FSDC 110 extends through a passivation layer 126 to make contact with the top of S/D 104b.

As shown in FIG. 1C, S/D 104a comprises a lower S/D portion, disposed above the substrate 116, comprising a high temperature silicide structure 128 and an etch stop layer (ESL) structure 130 surrounding at least a portion of the high temperature silicide structure 128, and further comprising an upper S/D portion, disposed above the lower S/D portion, comprising an epitaxial (EPI) material in contact with the ends of the vertically-stacked channels 120. The backside metal structure 112 extends through the substrate 116 and is in contact with the high temperature silicide structure 128.

FIG. 1D is a cross-sectional view of the semiconductor structure 100 along cut line A-A, according to other aspects of the disclosure. The semiconductor structure 100 shown in FIG. 1D is identical to that shown in FIG. 1C except that the high temperature silicide structure 128 extends up to the top of S/D 104a.

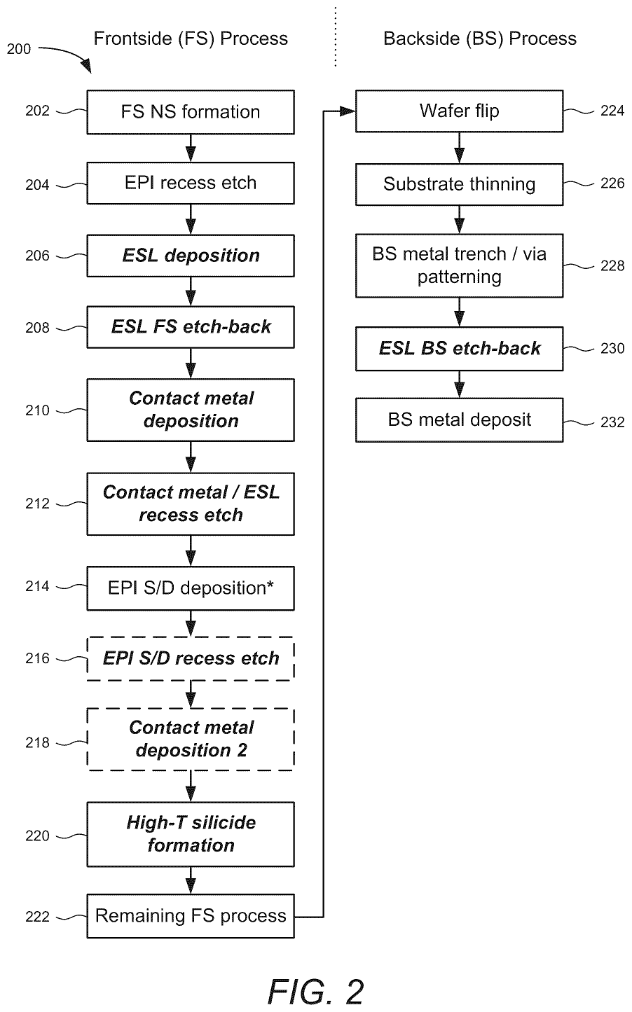

FIG. 2 is a process flow diagram illustrating steps in a process 200 for fabricating a semiconductor structure having a high-temperature silicide contact for backside S/D contacts, according to aspects of the disclosure. In the example shown in FIG. 2, the process 200 includes, at block 202, performing a frontside (FS) nanosheet (NS) formation process. This results in gate structures, such as the gates G1-G3 in FIG. 1C. The process 200 further includes, at block 204, performing an EPI recess etch process. The process 200 further includes, at block 206, performing an etch-stop layer (ESL) deposition process. The process 200 further includes, at block 208, performing an ESL FS etch-back process. The process 200 further includes, at block 210, performing a contact metal deposition process. This results in what will eventually be the high-temperature silicide structures, such as the high temperature silicide structure 128 in FIG. 1C. The process 200 further includes, at block 212, performing a contact metal and ESL recess etch process. This results in ESL structures, such as the ESL structures 130 in FIG. 1C. The process 200 further includes, at block 214, performing an EPI S/D deposition process. This results in S/D structures, such as the S/D structures S/D 104a and S/D 104b in FIG. 1C.

The process 200 further includes, at optional block 216, performing an EPI S/D recess etch process, and at optional block 218, performing a second contact metal deposition process. This results in what will eventually be the high-temperature silicide structures, such as the high temperature silicide structure 128 in FIG. 1D.

The process 200 further includes, at block 220, performing a high-temperature silicide formation process. In some aspects, this comprises annealing the contact metal deposited at block 210 (and at optional block 218, if performed). The process 200 further includes, at block 222, performing the remaining FS process steps. These steps produce the frontside structures, such as the FSDC 110 and the passivation layer 126 in FIG. 1C. A backside (BS) process is then performed starting from block 224.

The process 200 further includes, at block 224, performing a wafer flip. In some aspects, this comprises mounting a carrier structure to the top of the wafer and exposing the bottom surface of the substrate for further processing. The process 200 further includes, at block 226, performing a substrate thinning process. In some aspects, this may include a chemical/mechanical polishing (CMP) process. The process 200 further includes, at block 228, performing a BS metal trench/via patterning process. In some aspects, the substrate 116 in FIG. 1C, for example, is etched to reveal the bottom surface of the high temperature silicide structure 128. In some aspects, some of the ESL structure 130 may also be removed as part of this process. The process 200 further includes, at block 230, performing an ESL BS etch-back process. In some aspects, ESL structure 130 in FIG. 1C, for example, is further etched to reveal the sides of the high temperature silicide structure 128, e.g., so that the later-deposited contact metal has a larger contact area with the high-temperature silicide structure 128. The process 200 further includes, at block 232, performing a BS metal deposit process. This results in the backside metal structure 112 in FIG. 1C, for example. In some aspects, the backside metal structure 112 comprises a BSPDN contact.

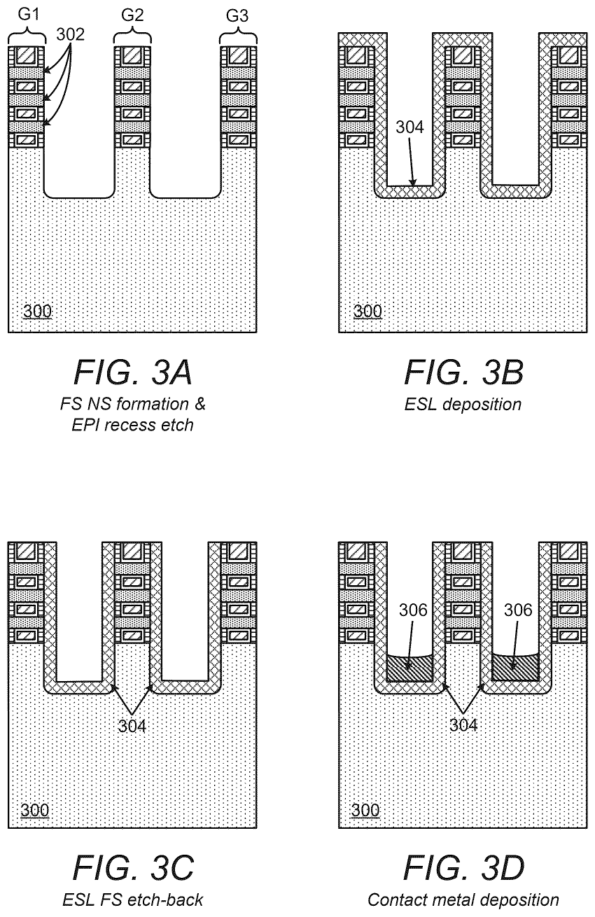

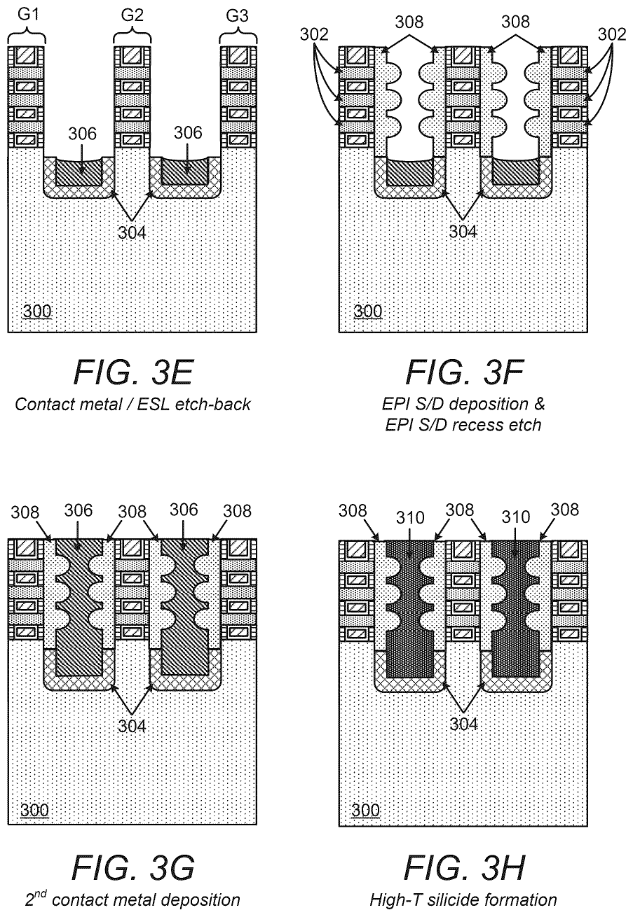

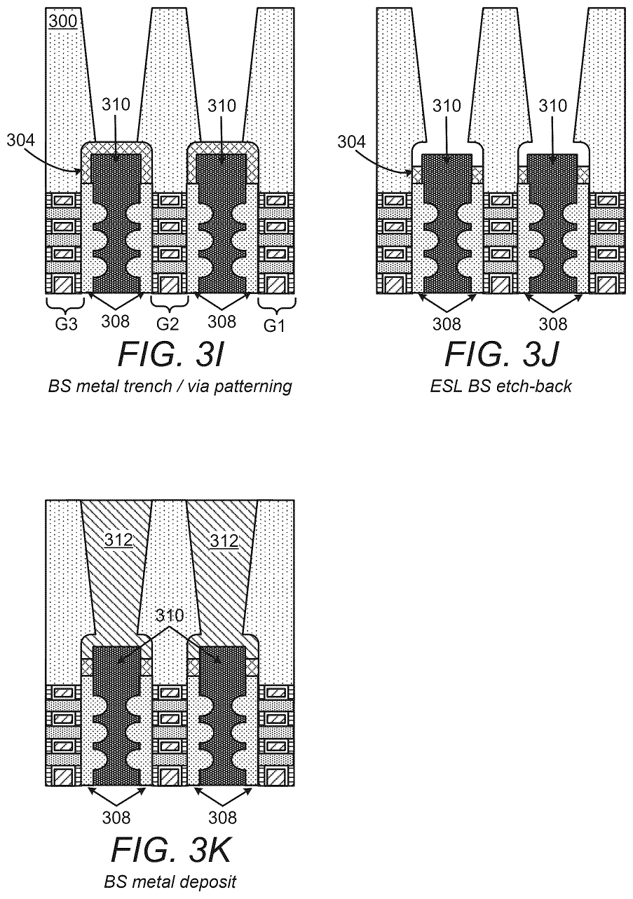

FIGS. 3A-3K are cross-sections that illustrate steps in a process for fabricating a semiconductor structure having a high-temperature silicide contact for backside S/D contacts, according to aspects of the invention. FIG. 3A shows the result after performing a frontside nano-sheet formation process and EPI recess etch, which leaves gate structures G1-G3 on substrate 300 separated by voids that will eventually be filled with EPI material to form S/D regions. Each gate structure includes a set of horizontal nanosheet channels 302. FIG. 3B shows the result after deposition of an etch stop layer (ESL) material 304. FIG. 3C shows the result after performing an ESL frontside etch-back. FIG. 3D shows the result after depositing contact metal structures 306 onto the ESL material 304 between the gate structures.

FIG. 3E shows the result after a contact metal/ESL etch-back process. This process removes the ESL material from the sides of the gate stacks. FIG. 3F shows the result after an EPI S/D deposition process and an EPI S/D recess etch. This results in the EPI S/D structures 308 that have grown from the channels 302. FIG. 3G shows the result after a second contact metal deposition process, which extends the contact metal structures 306 up to the top of the S/D structures 308. FIG. 3H shows the result after a high-temperature silicide formation process, which produces the high-temperature silicide structures 310.

FIG. 3I shows the result after a wafer flip and a backside metal trench/via patterning process, which exposes the ESL material 304. FIG. 3J shows the result after performing an ESL BS etch-back process, which removes a portion of the ESL material 304 to expose the high-temperature silicide structure 310. FIG. 3K shows the result after performing a backside metal deposit process, which produces BSDCs 312, each of which is in contact with a high-temperature silicide structure 310.

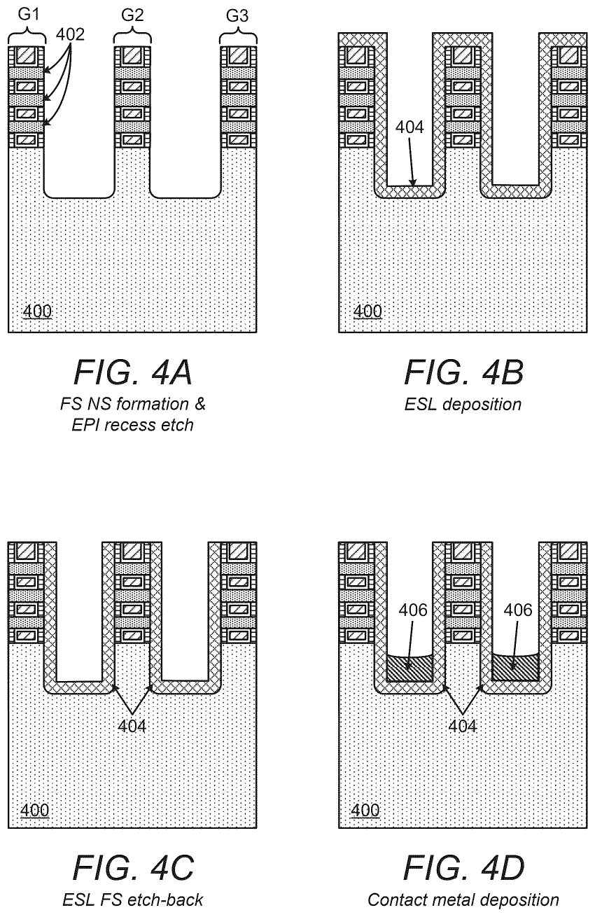

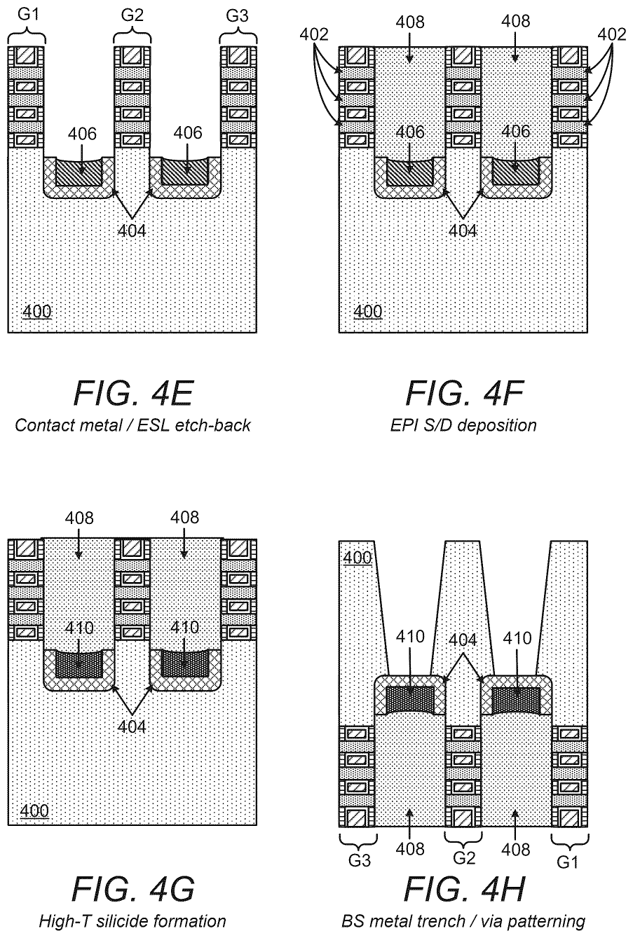

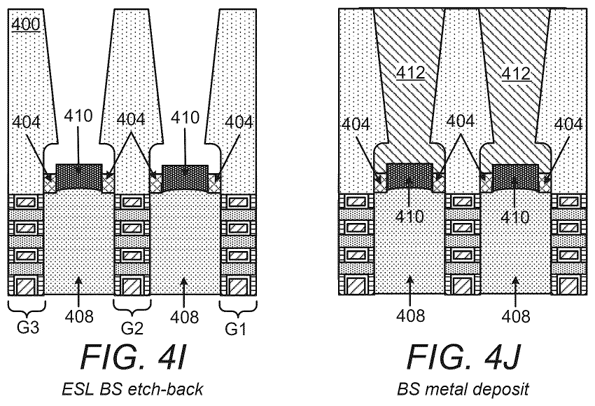

FIGS. 4A-4J are cross-sections that illustrate steps in a process for fabricating a semiconductor structure having a high-temperature silicide contact for backside S/D contacts, according to other aspects of the invention. FIG. 4A shows the result after performing a frontside nano-sheet formation process and EPI recess etch, which leaves gate structures G1-G3 on substrate 400 separated by voids that will eventually be filled with EPI material to form S/D regions. Each gate structure includes a set of horizontal nanosheet channels 402. FIG. 4B shows the result after deposition of an etch stop layer (ESL) material 404. FIG. 4C shows the result after performing an ESL frontside etch-back. FIG. 4D shows the result after depositing contact metal structures 406 onto the ESL material 404 between the gate structures.

FIG. 4E shows the result after a contact metal/ESL etch-back process. This process removes the ESL material from the sides of the gate stacks. FIG. 4F shows the result after an EPI S/D deposition process. This results in the EPI S/D structures 408 that have grown from the channels 402. FIG. 4G shows the result after a high-temperature silicide formation process, which produces the high-temperature silicide structures 410. FIG. 4H shows the result after a wafer flip and a backside metal trench/via patterning process, which exposes the etch stop layer 404.

FIG. 4I shows the result after performing an ESL BS etch-back process, which removes a portion of the etch stop layer 404 to expose the high-temperature silicide structure 410. FIG. 4J shows the result after performing a backside metal deposit process, which produces BSDCs 412, each of which is in contact with a high-temperature silicide structure 410.

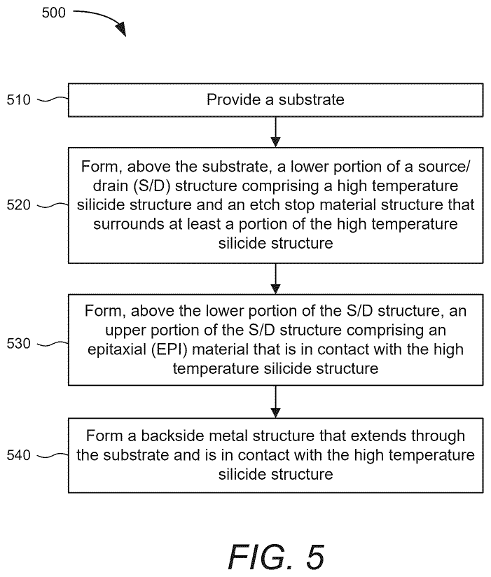

FIG. 5 is a flowchart of an example process 500 associated with fabricating a semiconductor structure having a high-temperature silicide contact for backside S/D contacts, according to aspects of the disclosure. In some aspects, the high-temperature silicide contact is part of a BSPDN. As shown in FIG. 5, process 500 may include, at block 510, providing a substrate. Example substrates include, but are not limited to, silicon (Si) and gallium arsenide (GaAs).

As further shown in FIG. 5, process 500 may include, at block 520, forming, above the substrate, a lower portion of a source/drain (S/D) structure comprising a high temperature silicide structure and an etch stop material structure that surrounds at least a portion of the high temperature silicide structure. In some aspects, forming the lower portion of the S/D structure comprises forming the etch stop material structure, depositing the high temperature silicide structure above the etch stop material structure, and annealing the high temperature silicide structure. In some aspects, annealing the high temperature silicide structure comprises annealing the high temperature silicide structure at a temperature of at least 350 degrees Celsius. In some aspects, annealing the high temperature silicide structure comprises annealing the high temperature silicide structure at a temperature of at least 750 degrees Celsius. In some aspects, forming the etch stop material structure comprises forming the etch stop material from at least one of silicon carbon nitride (SiCN), silicon carbon oxynitride (SiCON), aluminum nitride (AlN), or an area-selective deposition (ASD) dielectric. In some aspects, the high temperature silicide structure comprises at least one of titanium (Ti), cobalt (Co), or nickel (Ni).

As further shown in FIG. 5, process 500 may include, at block 530, forming, above the lower portion of the S/D structure, an upper portion of the S/D structure comprising an epitaxial (EPI) material that is in contact with the high temperature silicide structure. In some aspects, forming the upper portion of the S/D structure further comprises forming a frontside contact metal structure extending through the EPI material into contact metal that has been deposited in the lower portion of the S/D structure but not yet turned into silicide, and performing high temperature annealing of at least 750 degrees Celsius, which turns at least a portion of the contact metal in the upper and lower portions of the S/D structure into a high temperature silicide. As used herein, the term “frontside contact metal structure” refers to a contact metal structure that is formed using a frontside wafer process.

As further shown in FIG. 5, process 500 may include, at block 540, forming a backside metal structure that extends through the substrate and is in contact with the high temperature silicide structure. In some aspects, forming the backside metal structure that extends through the substrate and is in contact with the high temperature silicide structure comprises etching the substrate to expose the etch stop material, etching the etch stop material to expose at least a bottom surface of the high temperature silicide structure, and depositing metal onto at least the bottom surface of the high temperature silicide structure to form the backside metal structure. In some aspects, etching the etch stop material to expose at least the bottom surface of the high temperature silicide structure comprises etching the etch stop material to further expose a side surface of the high temperature silicide structure. In some aspects, forming the backside metal structure comprises forming a copper structure.

Process 500 may include additional implementations, such as any single implementation or any combination of implementations described below and/or in connection with one or more other processes described elsewhere herein. Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

Directional terms such as upper, lower, above, and below are used herein for ease of description and often refer to illustrations in the application figures. Such terms are not necessarily descriptive of a physical direction or disposition or positioning of a device.

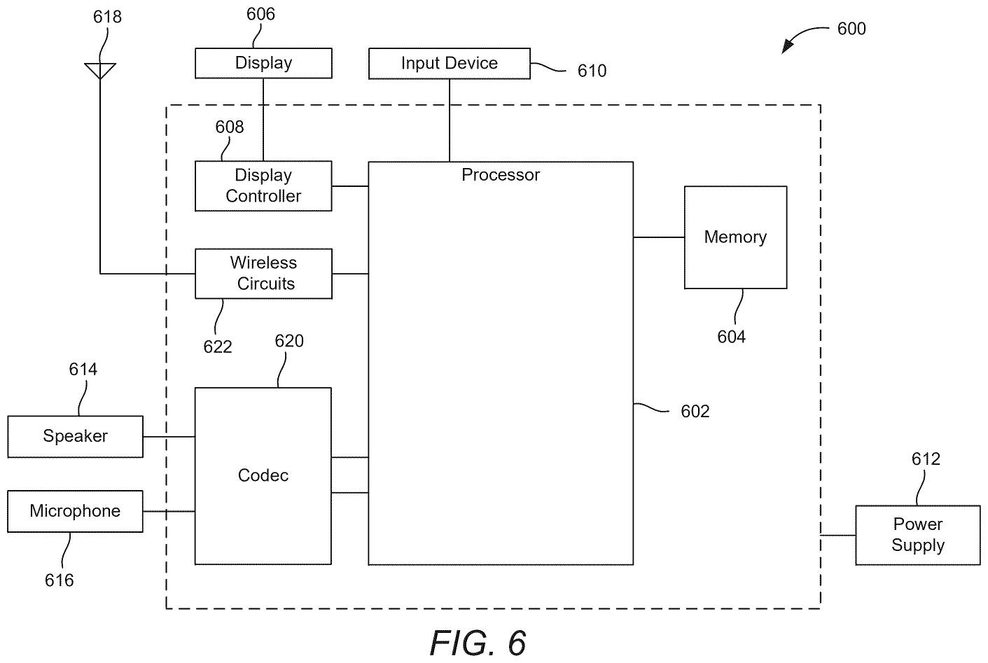

FIG. 6 illustrates a mobile device 600, according to aspects of the disclosure. In some aspects, the mobile device 600 may be implemented by including one or more IC devices manufactured based on the examples described in this disclosure.

In some aspects, mobile device 600 may be configured as a wireless communication device. As shown, mobile device 600 includes processor 602. Processor 602 may be communicatively coupled to memory 604 over a link, which may be a die-to-die or chip-to-chip link. Mobile device 600 also includes display 606 and display controller 608, with display controller 608 coupled to processor 602 and to display 606. The mobile device 600 may include input device 610 (e.g., physical, or virtual keyboard), power supply 612 (e.g., battery), speaker 614, microphone 616, and wireless antenna 618. In some aspects, the power supply 612 may directly or indirectly provide the supply voltage for operating some or all of the components of the mobile device 600.

In some aspects, FIG. 6 may include coder/decoder (CODEC) 620 (e.g., an audio and/or voice CODEC) coupled to processor 602; speaker 614 and microphone 616 coupled to CODEC 620; and wireless circuits 622 (which may include a modem, RF circuitry, filters, etc.) coupled to wireless antenna 618 and to processor 602.

In some aspects, one or more of processor 602, display controller 608, memory 604, CODEC 620, and wireless circuits 622 may include one or more IC devices including semiconductor structures manufactured according to the examples described in this disclosure.

It should be noted that although FIG. 6 depicts a mobile device 600, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

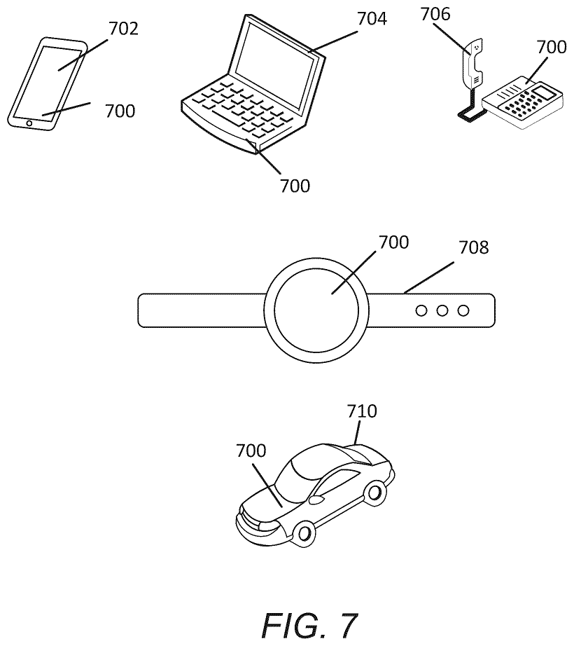

FIG. 7 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 702, a laptop computer device 704, a fixed location terminal device 706, a wearable device 708, or automotive vehicle 710 may include a semiconductor device 700 (e.g., semiconductor structure 100) as described herein. The devices 702, 704, 706 and 708 and the vehicle 710 illustrated in FIG. 7 are merely exemplary. Other apparatuses or devices may also feature the semiconductor device 700 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor structure, comprising: a substrate; a source/drain (S/D) structure comprising a lower S/D portion disposed above the substrate and an upper S/D portion disposed above the lower S/D portion, the lower S/D portion comprising a high temperature silicide structure and an etch stop material structure surrounding at least a portion of the high temperature silicide structure, the upper S/D portion comprising an epitaxial (EPI) material in contact with the high temperature silicide structure; and a backside metal structure that extends through the substrate and is in contact with the high temperature silicide structure.

Clause 2. The semiconductor structure of clause 1, wherein the high temperature silicide structure comprises a structure having an annealing temperature of at least 350 degrees Celsius.

Clause 3. The semiconductor structure of any of clauses 1 to 2, wherein the high temperature silicide structure comprises a structure having an annealing temperature of at least 750 degrees Celsius.

Clause 4. The semiconductor structure of any of clauses 1 to 3, wherein the S/D structure further comprises a frontside high temperature silicide contact structure extending through the EPI material of the upper S/D portion into the high temperature silicide structure of the lower S/D portion.

Clause 5. The semiconductor structure of any of clauses 1 to 4, wherein the backside metal structure is in contact with a bottom surface of the high temperature silicide structure.

Clause 6. The semiconductor structure of clause 5, wherein the backside metal structure is further in contact with a side surface of the high temperature silicide structure.

Clause 7. The semiconductor structure of any of clauses 1 to 6, wherein the etch stop material comprises at least one of silicon carbon nitride (SiCN), silicon carbon oxynitride (SiCON), aluminum nitride (AlN), or an area-selective deposition (ASD) dielectric.

Clause 8. The semiconductor structure of any of clauses 1 to 7, wherein the high temperature silicide structure comprises at least one of titanium (Ti), cobalt (Co), or nickel (Ni).

Clause 9. A method for fabricating a semiconductor structure, the method comprising: providing a substrate; forming, above the substrate, a lower portion of a source/drain (S/D) structure comprising a high temperature silicide structure and an etch stop material structure that surrounds at least a portion of the high temperature silicide structure; forming, above the lower portion of the S/D structure, an upper portion of the S/D structure comprising an epitaxial (EPI) material that is in contact with the high temperature silicide structure; and forming a backside metal structure that extends through the substrate and is in contact with the high temperature silicide structure.

Clause 10. The method of clause 9, wherein forming the lower portion of the S/D structure comprises: forming the etch stop material structure; depositing the high temperature silicide structure above the etch stop material structure; and annealing the high temperature silicide structure.

Clause 11. The method of clause 10, wherein annealing the high temperature silicide structure comprises annealing the high temperature silicide structure at a temperature of at least 350 degrees Celsius.

Clause 12. The method of any of clauses 10 to 11, wherein annealing the high temperature silicide structure comprises annealing the high temperature silicide structure at a temperature of at least 750 degrees Celsius.

Clause 13. The method of any of clauses 10 to 12, wherein forming the etch stop material structure comprises forming the etch stop material from at least one of silicon carbon nitride (SiCN), silicon carbon oxynitride (SiCON), aluminum nitride (AlN), or an area-selective deposition (ASD) dielectric.

Clause 14. The method of any of clauses 9 to 13, wherein forming the upper portion of the S/D structure further comprises: forming a frontside contact metal structure extending through the EPI material into the high temperature silicide structure in the lower portion of the S/D structure; and performing high temperature annealing of at least 750 degrees Celsius.

Clause 15. The method of any of clauses 9 to 14, wherein forming the backside metal structure that extends through the substrate and is in contact with the high temperature silicide structure comprises: etching the substrate to expose the etch stop material; etching the etch stop material to expose at least a bottom surface of the high temperature silicide structure; and depositing metal onto the least the bottom surface of the high temperature silicide structure to form the backside metal structure.

Clause 16. The method of clause 15, wherein etching the etch stop material to expose at least the bottom surface of the high temperature silicide structure comprises etching the etch stop material to further expose a side surface of the high temperature silicide structure.

Clause 17. The method of any of clauses 9 to 16, wherein forming the backside metal structure comprises forming a copper structure.

Clause 18. The method of any of clauses 9 to 17, wherein the high temperature silicide structure comprises at least one of titanium (Ti), cobalt (Co), or nickel (Ni).

Clause 19. An apparatus, comprising: a field effect transistor (FET) structure, wherein the FET structure comprises: a substrate; a gate structure, disposed above the substrate and comprising a vertical metal gate structure and a channel structure, the channel structure comprising a plurality of vertically-stacked channels extending horizontally through the vertical metal gate structure; a source/drain (S/D) structure, comprising a lower S/D portion, disposed above the substrate, comprising a high temperature silicide structure and an etch stop material structure surrounding at least a portion of the high temperature silicide structure, and further comprising an upper S/D portion, disposed above the lower S/D portion, comprising an epitaxial (EPI) material in contact with a first end of each vertically-stacked channel of the plurality of vertically-stacked channels; and a backside metal structure that extends through the substrate and is in contact with the high temperature silicide structure.

Clause 20. The apparatus of clause 19, wherein the S/D structure further comprises a frontside high temperature silicide contact structure extending through the EPI material of the upper S/D portion into the high temperature silicide structure of the lower S/D portion.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a substrate;
a source/drain (S/D) structure comprising a lower S/D portion disposed above the substrate and an upper S/D portion disposed above the lower S/D portion, the lower S/D portion comprising a high temperature silicide structure and an etch stop material structure surrounding at least a portion of the high temperature silicide structure, the upper S/D portion comprising an epitaxial (EPI) material in contact with the high temperature silicide structure; and
a backside metal structure that extends through the substrate and is in contact with the high temperature silicide structure.

2. The semiconductor structure of claim 1, wherein the high temperature silicide structure comprises a structure having an annealing temperature of at least 350 degrees Celsius.

3. The semiconductor structure of claim 1, wherein the high temperature silicide structure comprises a structure having an annealing temperature of at least 750 degrees Celsius.

4. The semiconductor structure of claim 1, wherein the S/D structure further comprises a frontside high temperature silicide contact structure extending through the EPI material of the upper S/D portion into the high temperature silicide structure of the lower S/D portion.

5. The semiconductor structure of claim 1, wherein the backside metal structure is in contact with a bottom surface of the high temperature silicide structure.

6. The semiconductor structure of claim 5, wherein the backside metal structure is further in contact with a side surface of the high temperature silicide structure.

7. The semiconductor structure of claim 1, wherein the etch stop material comprises at least one of silicon carbon nitride (SiCN), silicon carbon oxynitride (SiCON), aluminum nitride (AlN), or an area-selective deposition (ASD) dielectric.

8. The semiconductor structure of claim 1, wherein the high temperature silicide structure comprises at least one of titanium (Ti), cobalt (Co), or nickel (Ni).

9. A method for fabricating a semiconductor structure, the method comprising:
providing a substrate;
forming, above the substrate, a lower portion of a source/drain (S/D) structure comprising a high temperature silicide structure and an etch stop material structure that surrounds at least a portion of the high temperature silicide structure;
forming, above the lower portion of the S/D structure, an upper portion of the S/D structure comprising an epitaxial (EPI) material that is in contact with the high temperature silicide structure; and
forming a backside metal structure that extends through the substrate and is in contact with the high temperature silicide structure.

10. The method of claim 9, wherein forming the lower portion of the S/D structure comprises:
forming the etch stop material structure;
depositing the high temperature silicide structure above the etch stop material structure; and
annealing the high temperature silicide structure.

11. The method of claim 10, wherein annealing the high temperature silicide structure comprises annealing the high temperature silicide structure at a temperature of at least 350 degrees Celsius.

12. The method of claim 10, wherein annealing the high temperature silicide structure comprises annealing the high temperature silicide structure at a temperature of at least 750 degrees Celsius.

13. The method of claim 10, wherein forming the etch stop material structure comprises forming the etch stop material from at least one of silicon carbon nitride (SiCN), silicon carbon oxynitride (SiCON), aluminum nitride (AlN), or an area-selective deposition (ASD) dielectric.

14. The method of claim 9, wherein forming the upper portion of the S/D structure further comprises:
forming a frontside contact metal structure extending through the EPI material into the high temperature silicide structure in the lower portion of the S/D structure; and
performing high temperature annealing of at least 750 degrees Celsius.

15. The method of claim 9, wherein forming the backside metal structure that extends through the substrate and is in contact with the high temperature silicide structure comprises:
etching the substrate to expose the etch stop material;
etching the etch stop material to expose at least a bottom surface of the high temperature silicide structure; and
depositing metal onto the least the bottom surface of the high temperature silicide structure to form the backside metal structure.

16. The method of claim 15, wherein etching the etch stop material to expose at least the bottom surface of the high temperature silicide structure comprises etching the etch stop material to further expose a side surface of the high temperature silicide structure.

17. The method of claim 9, wherein forming the backside metal structure comprises forming a copper structure.

18. The method of claim 9, wherein the high temperature silicide structure comprises at least one of titanium (Ti), cobalt (Co), or nickel (Ni).

19. An apparatus, comprising:
a field effect transistor (FET) structure, bwherein the FET structure comprises:
a substrate;
a gate structure, disposed above the substrate and comprising a vertical metal gate structure and a channel structure, the channel structure comprising a plurality of vertically-stacked channels extending horizontally through the vertical metal gate structure;
a source/drain (S/D) structure, comprising a lower S/D portion, disposed above the substrate, comprising a high temperature silicide structure and an etch stop material structure surrounding at least a portion of the high temperature silicide structure, and further comprising an upper S/D portion, disposed above the lower S/D portion, comprising an epitaxial (EPI) material in contact with a first end of each vertically-stacked channel of the plurality of vertically-stacked channels; and
a backside metal structure that extends through the substrate and is in contact with the high temperature silicide structure.

20. The apparatus of claim 19, wherein the S/D structure further comprises a frontside high temperature silicide contact structure extending through the EPI material of the upper S/D portion into the high temperature silicide structure of the lower S/D portion.
